(19) United States
(12) Patent Application Publication
(10) Pub. No.: US 2007/0011506 A1
(43) Pub. Date: Jan. 11, 2007

(54) Semiconductor integrated circuit verifying and inspecting method

(76) Inventor: Takaki Yoshida, Osaka (JP)

Correspondence Address: MCDERMOTT WILL & EMERY LLP, 600 13TH STREET, N.W., WASHINGTON, DC, 20005-3096, US

(21) Appl. No.: 11/480,411

(22) Filed: Jul. 5, 2006

(30) Foreign Application Priority Data
Jul. 5, 2005 (JP) P2005-196138

(51) Int. Cl. G01R 31/28

(52) U.S. Cl. 714/712; 714/715

(57) ABSTRACT

A method of verifying a semiconductor integrated circuit according to the invention does not compare expected values based on a strobe every cycle but executes a verification on the basis of a signal transition (change) point. At the same time, the verifying method is intended for verifying a path in a circuit through which a signal transition (change) in a result to be output is sent, and can find the drawbacks of a circuit and a pattern in a more upstream process for a design with higher precision as compared with the conventional art so that quality of a design can be enhanced. By using information about the path through which the signal transition is output to carry out an inspection, moreover, it is possible to finally inspect (test) an LSI with high precision and quality.

### BACKGROUND OF THE INVENTION

1. Field of the Invention

The present invention relates to a method of verifying and inspecting a semiconductor integrated circuit which can efficiently verify and inspect (test) a semiconductor integrated circuit with high precision.

2. Description of the related art

A final LSI (product) is inspected by inputting a test pattern in the LSI using an inspecting device. In order to stably carry out the inspection, it is necessary to carry out a sufficient verification for obtaining a test pattern in consideration of a variation in a process, a temperature and a voltage of the LSI and a limitation in the inspecting device.

A conventionally general method of creating a test pattern is as follows:
1) An event driven simulation on an original RTL (Resistor Transfer Level) is carried out to confirm an event driven output operation;
2) An event driven logical simulation result is cut out every cycle in order to obtain a test pattern for an inspection, and a strobe time is set to a time that the output operation can be decided and is set to be a basic expected value;
3) A simulation on a gate level (for example, an MIN or MAX mode) is carried out in order to withstand variations (in this case, whether the strobe time has the basic expected value is checked, and the strobe is set to be a certain time depending on each mode);
4) If a circuit operation is OK, a range to be passed in MIN and MAX in order to obtain a stability in the inspecting device is set to be the strobe time and an unnecessary portion is masked (omitted) (the expected values are not compared with each other); and
5) A decision of pass and fail is carried out through a comparison of the expected values in the strobe time every cycle.

Referring to the conventional logical simulation verification and inspection, thus, a strobe is set in a proper time to compare the expected values of HHLLZ every cycle in the case in which an output expecting operation is confirmed as is schematically shown in FIG. 1. In other words, in the case in which an inspection is basically carried out, a strobe base is set.

There has been proposed an inspecting device for projecting the elimination of a work for replacing an original event driven result on a cycle basis and reading an event driven simulation result, and exactly carrying out an inspection (JP-A-9-318713 Publication). In this case, a transition time of a signal in a logical simulation and a transition time of a signal in an actual LSI inspection in the inspecting device are to be processed on completely the same conditions. However, it is impossible to cause the condition of the logical simulation to be perfectly coincident with the condition of the inspection for the LSI. As a result, it is impossible to decide whether the transition time of the signal in the logical simulation which is read is accurate or not in the actual LSI.

In the LSI, when a certain input is given, only a signal passing through a path in a circuit influences an output so that a transition of the signal at an output terminal is generated. When the circuit is operated accurately, an output transition is generated through an expected path. Consequently, the transition of the signal is generated in a time expected every cycle. To the contrary, there is a possibility that the circuit might not be designed accurately if the transition of the signal is not generated in the time expected in a certain cycle. In other words, it is to be decided whether an original circuit operation is accurate or not depending on a time that the transition of the signal is generated every cycle. In an inspecting method employed under the existing circumstances, however, a simulation result is cut out in order to compare expected values every cycle. Although the cut-out work gives a design to have a stable strobe, it might be insensitive to the operation of the circuit.

Detailed description will be given with reference to the drawings. Usually, a signal output from an LSI and passing through one of a plurality of paths is output as a transition waveform. For example, in FIG. 2, a signal output from OUT1 passes through any of paths A to F to generate an output transition. As shown in FIG. 3, it is assumed that the signal rises in different times in the paths A, B and E. When a conventional strobe is set in the time shown in FIG. 3, however, the signals output from all of the paths A, B and E pass therethrough. In other words, there is a problem in that the path A cannot be distinguished from the paths B and E in the present verifying method even if it is accurate.

In the technique described in the JP-A-9-318713 Publication, therefore, attention is paid to the transition time of a signal. However, a simulation is simply fetched exactly and an inspection for deciding quality of an LSI is not taken into consideration. For this reason, there is a problem in that the quality of the LSI cannot be decided with high precision.

### SUMMARY OF THE INVENTION

The invention has been made in consideration of the actual circumstances and has an object to solve the problems and to efficiently verify an LSI with high precision, thereby carrying out a stable inspection (test).

A method of verifying a semiconductor integrated circuit according to the invention does not compare expected values on the basis of a strobe as in the conventional art but carries out the verification on the basis of a signal transition (change) point. At the same time, any of paths in a circuit through which the signal transition (change) in an output result passes is set to be a verifying object. As compared with the conventional verifying method, it is possible to find the drawbacks of a circuit and a pattern in a more upstream process of a design with higher precision so that quality of the design can be enhanced. Moreover, an inspection is carried out by using information about any path through which the signal transition is output. Finally, the LSI can be inspected (tested) with high precision and quality.

More specifically, the invention provides a method of verifying a semiconductor integrated circuit which sets an expected value comparing time onto a signal transition point and verifying whether a circuit is operated accurately or not.

By this structure, the expected values are not compared on the basis of a strobe but the verification is carried out on the basis of a signal transition (change) point. Therefore, it is possible to extract features without increasing a time required for a processing, thereby carrying out a detection with high precision.

Moreover, the invention provides the method of verifying a semiconductor integrated circuit, comprising a path extracting step of extracting a path in a circuit through which a signal is output based on circuit information of a semiconductor integrated circuit and signal transition information of the semiconductor integrated circuit, whether the circuit is operated accurately being verified.

By this structure, whether the circuit is operated accurately is verified based on how to generate a transition of a signal output through any of the paths in place of the strobe for each cycle. Therefore, the verification can be carried out with high precision in a small amount of calculations. It is possible to execute the path extracting step by using a path extracting mechanism.

Furthermore, the invention provides the method of verifying a semiconductor integrated circuit, wherein whether a circuit is operated accurately is verified based on information about a path in a circuit through which a signal output from an external terminal of the semiconductor integrated circuit passes which is obtained by using information extracted at the path extracting step.

By this structure, whether the circuit is operated accurately is verified based on how to generate a transition of the signal output from the external terminal through any of the paths in place of the strobe for each cycle. Therefore, the verification can be carried out with high precision in a small amount of calculations. It is possible to execute the path extracting step by using the path extracting mechanism.

In addition, the invention provides the method of verifying a semiconductor integrated circuit, wherein the path extracting step serves to set an expected value comparing time onto a signal transition point obtained from the signal transition information and to extract a path.

By this structure, whether the circuit is operated accurately is verified based on how to generate a transition of a signal output through any of the paths in place of the strobe for each cycle. Therefore, the verification can be carried out with high precision in a small amount of calculations. It is possible to execute the path extracting step by using a path extracting mechanism.

Moreover, the invention provides the method of verifying a semiconductor integrated circuit, wherein the path extracting step serves to set an expected value comparing time onto a signal transition point and a signal stabilizing section and to extract a path.

By this structure, the path can be extracted with higher precision.

Furthermore, the invention provides the method of verifying a semiconductor integrated circuit, wherein the path extracting step serves to set an expected value comparing time based on a signal transition point obtained from an inspecting device and to extract a path.

In addition, the invention provides the method of verifying a semiconductor integrated circuit, wherein the path extracting step serves to set an expected value comparing time onto a signal transition point in the earliest case and a signal transition point in the latest case when a signal might be extended across a plurality of cycles.

By this structure, it is possible to carry out a detection well also in the case in which the signal transition point is extended across a plurality of cycles.

Moreover, the invention provides the method of verifying a semiconductor integrated circuit, wherein the path extracting step is executed by a path extracting mechanism for extracting a path which indicates a path in a circuit through which a signal is output from an external terminal in an operation of the semiconductor integrated circuit.

By this structure, the verification can be efficiently carried out with high precision.

Furthermore, the invention provides the method of verifying a semiconductor integrated circuit, wherein a path is decided by a path deciding mechanism for deciding a path which indicates a path in a circuit through which a signal is output from an external terminal in an operation of the semiconductor integrated circuit from path information extracted at the path extracting step.

In addition, the invention provides the method of verifying a semiconductor integrated circuit, comprising a comparing step of comparing a change in a path through which a signal is output from an external terminal in the case in which delay information is taken into consideration and the case in which the delay information is not taken into consideration, whether a circuit is operated accurately being verified based on a result of the comparison.

By this structure, if a difference is not made on the signal path between the case in which the verification is carried out with a zero delay or a unit delay and the case in which the verification is carried out with an ordinary delay, a delay margin is sufficiently maintained and a critical design portion is not present. Consequently, it is possible to decide that a synchronization is maintained in the circuit. On the other hand, if the difference is made, it is possible to find a possibility that a circuit might have a problem in that the delay margin is not sufficiently maintained and the critical design portion is present. In particular, it is possible to limit and examine any portion of the circuit which has a problem by confirming a resultant terminal, a path and transition information (an expected operation is not carried out in any terminal, any path and any transition). Consequently, it is possible to carry out the verification more efficiently with higher precision.

Moreover, the invention provides the method of verifying a semiconductor integrated circuit, wherein it is ascertained whether a path through which a signal is output from an external terminal is changed or not in the case in which delay information is taken into consideration and the case in which the delay information is not taken into consideration in a wiring delay and a cell delay, and whether a circuit is operated accurately is thus verified.

By this structure, it is possible to carry out the verification more efficiently with higher precision.

Furthermore, the invention provides the method of verifying a semiconductor integrated circuit, wherein a circuit operating frequency is varied to ascertain whether a path through which a signal is output from an external terminal is changed or not, and whether a circuit is operated accurately is thus verified.

By this structure, it is possible to carry out the verification more efficiently with higher precision.

In addition, the invention provides the method of verifying a semiconductor integrated circuit, further comprising a step of previously omitting a result comparison which does not require an expected value comparison by means of an expected value comparing unnecessary portion extracting mechanism prior to the path extracting step.

By this structure, it is possible to carry out the verification more efficiently with higher precision.

Moreover, the invention provides the method of verifying a semiconductor integrated circuit, further comprising a step of previously omitting an expected value comparison for a path in which a path frequency has a predetermined value or less by means of a path frequency extracting mechanism for extracting information about a frequency of a path through which a signal is sent prior to the path extracting step.

By this structure, it is possible to carry out the verification more efficiently with higher precision.

Furthermore, the invention provides the method of verifying a semiconductor integrated circuit, further comprising a step of extracting a signal path which causes an overcycle.

By this structure, it is possible to carry out the verification more efficiently with higher precision.

In addition, the invention provides the method of verifying a semiconductor integrated circuit, further comprising a step of extracting a signal path in which a signal transition is carried out at plural times in the same cycle.

Moreover, the invention provides the method of verifying a semiconductor integrated circuit, further comprising a step of extracting a cycle in which an expected value comparison cannot be stably carried out in a plurality of delay modes.

Furthermore, the invention provides the method of verifying a semiconductor integrated circuit, further comprising a step of giving a delay variation when extracting a path.

By this structure, it is possible to guess the degree of the delay margin by giving a delay variation.

In addition, the invention provides the method of verifying a semiconductor integrated circuit, wherein whether a circuit is operated accurately is inspected by using information about a path in the circuit through which a signal is output in an operation of the semiconductor integrated circuit.

By this structure, it is possible to implement an inspection with high precision and efficiency.

As described above, according to the invention, it is possible to find the drawbacks of a circuit and a pattern in a more upstream process for a design with high precision, thereby enhancing quality of the design. Moreover, the verification and inspection is carried out by using information about any path through which a signal transition is output. Finally, it is possible to inspect (test) an LSI with high precision and quality.

### BRIEF DESCRIPTION OF THE DRAWINGS

FIG. 1 is a conceptual diagram showing an ordinary logical simulation verification and inspection,

FIG. 2 is a circuit diagram for explaining a concept of the ordinary logical simulation verification and inspection and a verifying method and an inspecting method according to a first embodiment of the invention,

FIG. 3 is a conceptual diagram for explaining the verifying and inspecting method according to the first embodiment of the invention,

FIG. 4 is a signal transition diagram for explaining the verifying and inspecting method according to the first embodiment of the invention,

FIG. 5 is a diagram showing a basic structure of the verifying and inspecting method according to the first embodiment of the invention,

FIG. 6 is a flowchart showing a path extracting method according to the first embodiment of the invention,

FIG. 7 is a diagram showing an example of a dynamic simulation result in the path extracting method according to the first embodiment of the invention,

FIG. 8 is a diagram showing an example of a static timing analysis result in the path extracting method according to the first embodiment of the invention,

FIG. 9 is a diagram showing a result deciding mechanism in a verifying and inspecting method according to a second embodiment of the invention,

FIG. 10 is a diagram showing a difference in a delay condition between a simulation verification and an inspection according to the second embodiment of the invention,

FIG. 11 is a diagram showing an example in which a plurality of paths cannot be distinguished from each other in the inspection according to the second embodiment of the invention,

FIG. 12 is a diagram showing a verifying and inspecting method for a multicycle path according to the second embodiment of the invention,

FIG. 13 is a flowchart showing a basic of a verifying and inspecting method according to a third embodiment of the invention,

FIG. 14 is a diagram showing an example of signal transition information in the verifying and inspecting method according to the third embodiment of the invention,

FIG. 15 is a diagram showing an example of path signal delay information in the verifying and inspecting method according to the third embodiment of the invention,

FIG. 16 is a diagram showing an example of the signal transition information of a multicycle path in the verifying and inspecting method according to the third embodiment of the invention,

FIG. 17 is a flowchart showing a basis of a failure verifying method according to a fifth embodiment of the invention,

FIG. 18 is a flowchart showing an example in which an expected value comparing unnecessary portion is extracted according to a sixth embodiment of the invention,

FIG. 19 is a flowchart showing an example in which a path extracting and deciding mechanism is caused to have an expected value comparing unnecessary portion extracting mechanism according to the sixth embodiment of the invention,

FIG. 20 is a diagram showing an example of a path frequency list according to the sixth embodiment of the invention,

FIG. 21 is a circuit diagram for explaining a technique obtained by combining an edge base technique with a conventional strobe base technique according to the sixth embodiment of the invention,

FIG. 22 is a flowchart showing the technique obtained by combining the edge base technique with the conventional strobe base technique according to the sixth embodiment of the invention,

FIG. 23 is a diagram showing an example of information clearly describing an expected value comparing unnecessary portion in the technique obtained by combining the edge base technique with the conventional strobe base technique according to the sixth embodiment of the invention,

FIG. 24 is a diagram showing the summary of the technique obtained by combining the edge base technique with the conventional strobe base technique according to the sixth embodiment of the invention,

FIG. 25 is a diagram showing a concept of a technique obtained by adding a function of previously ascertaining whether a signal causes an overcycle or not according to a seventh embodiment of the invention,

FIG. 26 is a flowchart showing the technique obtained by adding the function of previously ascertaining whether a signal causes an overcycle or not according to the seventh embodiment of the invention,

FIG. 27 is a flowchart showing a technique obtained by adding a function of previously confirming the case in which at least two transitions are present in the same cycle according to the seventh embodiment of the invention,

FIG. 28 is a diagram showing a concept of a technique obtained by adding a function of previously ascertaining whether an expected value disappears in a plurality of delay modes according to the seventh embodiment of the invention,

FIG. 29 is a flowchart showing the technique obtained by adding the function of previously ascertaining whether an expected value disappears in a plurality of delay modes according to the seventh embodiment of the invention,

FIG. 30 is a flowchart showing a technique for giving a delay variation range according to an eighth embodiment of the invention,

FIG. 31 is a diagram showing a basic structure of a verifying and inspecting method using a plurality of clocks according to the eighth embodiment of the invention, and

FIG. 32 is a diagram showing an output waveform in the verifying and inspecting method using a plurality of clocks according to the eighth embodiment of the invention.

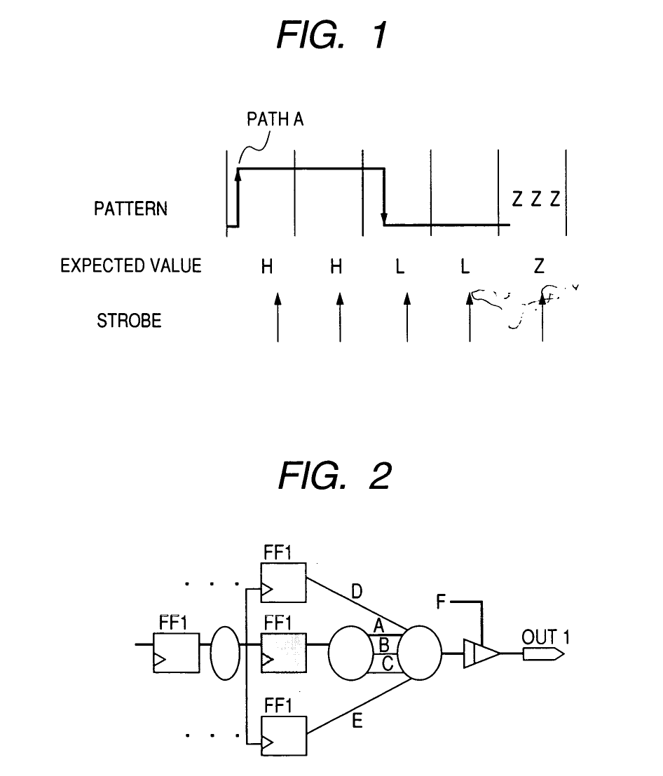

### DESCRIPTION OF THE PREFERRED EMBODIMENTS

Embodiments of the invention will be described below in detail with reference to the drawings.

FIGS. 2 to 8 are explanatory views showing a first embodiment of the invention.

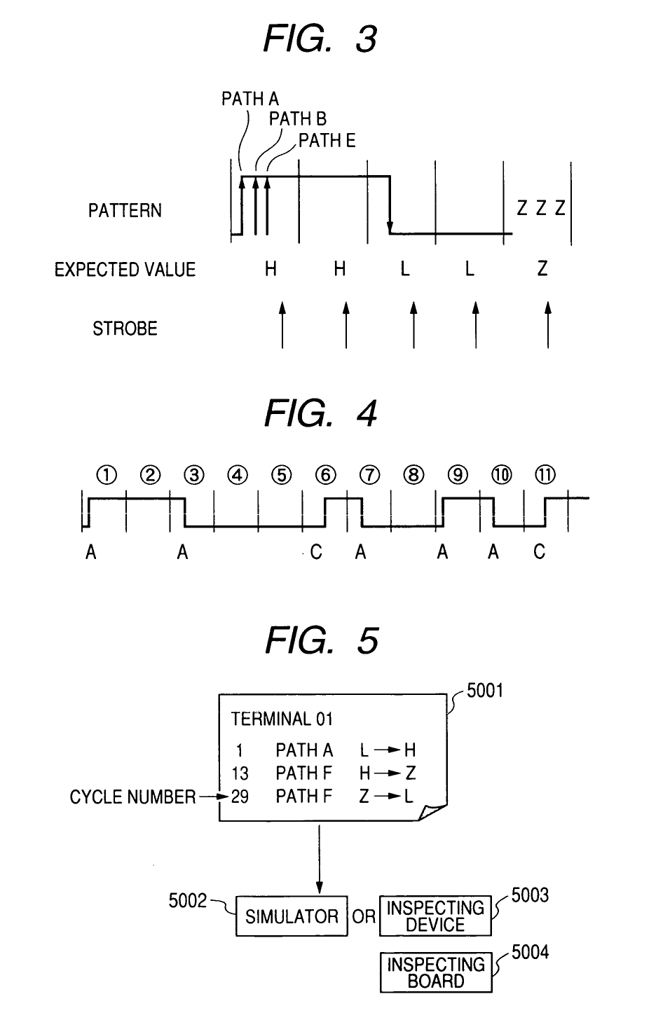

Usually, a signal passing through one of a plurality of paths is output as a transition waveform from an LSI. For example, in FIG. 2, a signal output from OUT1 passes through any of paths A to F to carry out an output transition. As shown in FIG. 3, it is assumed that the signal rises in different times from each other in the paths A, B and E.

In a conventional logical simulation verification for an inspection, a strobe is set every cycle to compare expected values with each other. If the expected values are compared with each other in a time shown in FIG. 3, therefore, signals output from all of paths A, B and E pass. In other words, there is a possibility that an operation failure might be missed because of an insensitivity to the operation of a circuit.

Therefore, a method according to the first embodiment of the invention serves to verify whether a circuit is operated accurately based on any path through which a signal is output and any transition thereof in place of a strobe for each cycle. For example, in the case in which a signal transition shown in FIG. 4 is generated in a circuit of FIG. 2, it is verified whether a signal is output through the path A in a first cycle to carry out a transition of L→H or is output through the path A in a third cycle to carry out a transition of H→L.

More specifically, FIG. 5 shows an example of a verifying device in which a cycle number, a path and a signal transition at a certain terminal are input as input information (which will be hereinafter referred to as signal transition information 5001) to a simulator (verifying device) 5002 for carrying out a verification and an inspecting device 5003. The inspecting device also includes an inspecting board 5004.

The input information serves as a basis of an operation of an LSI, and is also supposed to be generated from a system verification on an upstream of a design. Moreover, the input information may include information about only a cycle in which a signal transition is generated, and it is not necessary to have input/output information about all cycles as in the conventional art. Therefore, it is also possible to expect the effect of reducing a size of the input information.

While the description has been given to an output signal of an external terminal in an operation of a semiconductor integrated circuit, the invention can also be applied to an internal verification of an inner part of the circuit.

According to the method in accordance with the embodiment, thus, it is possible to find the drawbacks of a circuit and a pattern in a more upstream process for a design with higher precision as compared with the conventional verifying method, resulting in an enhancement in quality of the design. Moreover, an inspection is carried out by using information about any path through which a signal transition is output. Finally, it is possible to finally inspect (test) the LSI with high precision and high quality.

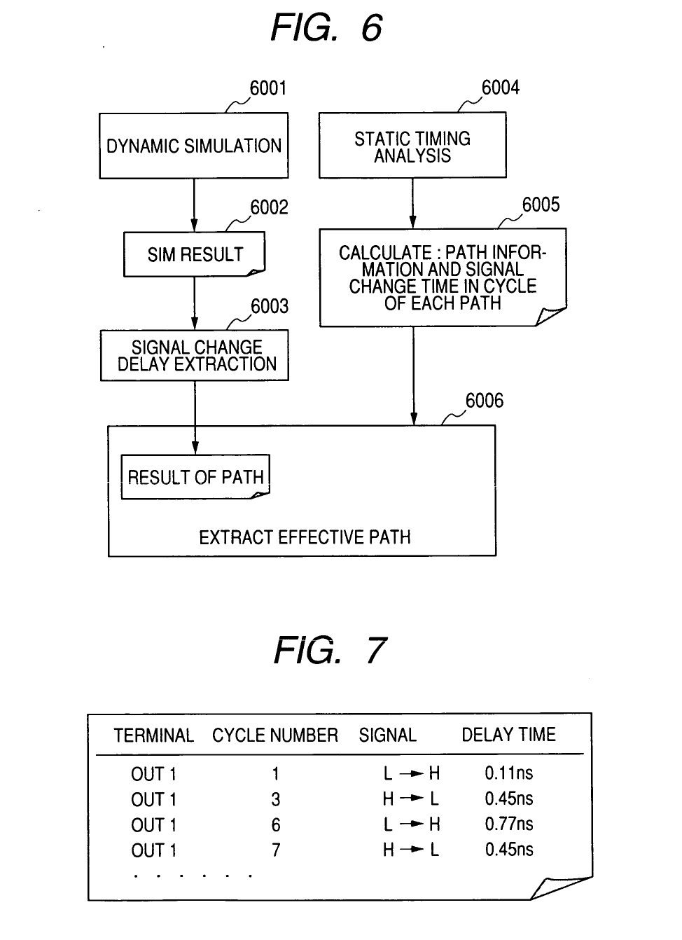

Next, a technique for extracting a path for a signal by using the verifying device illustrated in FIG. 5 is shown in FIGS. 6 to 8. The extracting method includes a step of carrying out a dynamic simulation (dynamic analysis) over the circuit (Step 6001), a step of extracting a signal change delay based on an SIM (simulation) result 6002 (Step 6003), a step of carrying out a static timing analysis over the circuit (Step 6004), a step of calculating information about a path and a transition time of a signal in a cycle of each path (calculating step 6005), and a step of extracting an effective path based on the signal change delay and a delay time of the signal in the cycle (effective path extracting step 6006), and the effective path is thus extracted. The transition time of the signal indicates a time that a transition of the signal is generated on the basis of a certain reference time, that is, a transition point.

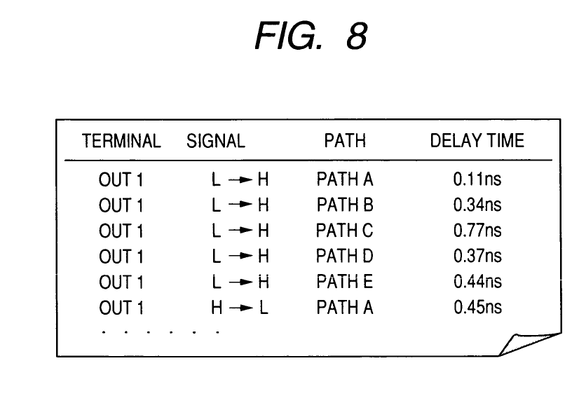

For example, it is assumed that the SIM result 6002 is obtained as shown in FIG. 4 by carrying out the dynamic simulation (dynamic analysis) over the circuit illustrated in FIG. 2. Referring to a specific change in a signal, FIG. 7 shows a time (transition time) that a clock to be an object is changed and the signal OUT1 is then changed. On the other hand, it is possible to calculate a signal delay in a path of a circuit to be a target by using the static timing analysis. In consideration of an example of the circuit shown in FIG. 2, a result shown in FIG. 8 can be calculated as a result of the processing at the calculating step 6005 based on the static timing analyzing step 6004. Referring to a rise of L→H, five paths can be proposed and have respective delay times. If a check is carried out together with the result of the path based on the dynamic simulation shown in FIG. 7, it is apparent that the signal is output through a path A in a first cycle, a path A in a third cycle, a path C in a sixth cycle and a path A in a seventh cycle in the simulation.

A specific flow is shown in FIG. 6. By using the static timing analysis (6004) and the dynamic analysis (dynamic simulation) result (6002), thus, it is possible to specify a path which is effective in the simulation.

### SECOND EMBODIMENT

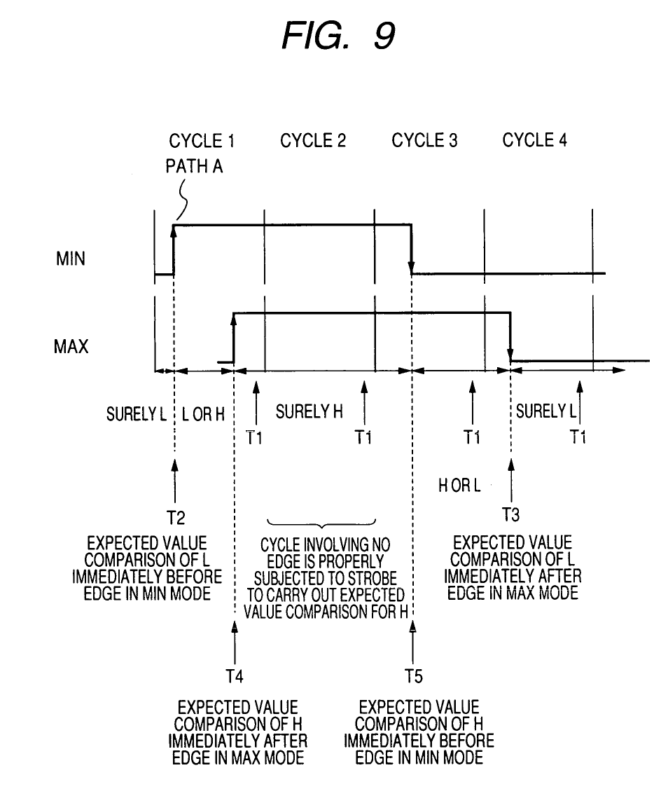

Next, a second embodiment of the invention will be described. FIGS. 9 to 12 illustrate a second embodiment of the invention.

A signal transition time output from an actual LSI is varied depending on a process, a temperature and a voltage. FIG. 9 shows a signal state set in the cases in which a signal delay is MIN and MAX. Conventionally, a strobe time has been set in an expected value comparing time which is resistant to a variation (T1).

On the other hand, in the second embodiment of the invention, the expected value comparing time is set to a signal transition time having a variation. An actual signal fluctuates between MIN and MAX. Based on an observation of a change in the signal, an “L” signal is surely set before T2, an “L” or “H” signal is set from T2 to T4, the “H” signal is surely set from T4 to T5, the “H” or “L” signal is set from T5 to T3, and the “L” signal is surely set after T3.

In the method according to the invention, an expected value comparing time is set to T2 to be a time that the signal carries out a transition at MIN and T3 that the signal carries out the transition at MAX. If necessary, furthermore, precision can be enhanced by setting the expected value comparing time to the signal transition T4 at MAX and the signal transition T5 at MIN. In a cycle 2, the “H” signal is surely set. When a time that the expected values are compared with each other is set to a suitable time in this cycle, the precision can further be enhanced. The expected value comparing time will be described in detail. For example, referring to T2, it is confirmed that the “L” signal is set immediately before T2 and a transition from “L” to “H” is carried out at T2. Similarly, it is confirmed that a transition from “H” to “L” is carried out at T3 and the “L” signal is set immediately after T3. Referring to “immediately before” and “immediately after”, for example, it can be supposed that a time before or after one unit on a minimum time unit is set. For example, if the minimum time unit is 1 ps, 129 ps is set immediately before 130 ps.

By using the method according to the invention, it is possible to reliably verify any path through which a signal is output. As compared with the conventional expected value comparison, consequently, it is possible to carry out the verification with higher precision. The invention according to the invention can also be applied to an inspection in an inspecting device and can carry out the inspection with higher precision than a conventional inspection.

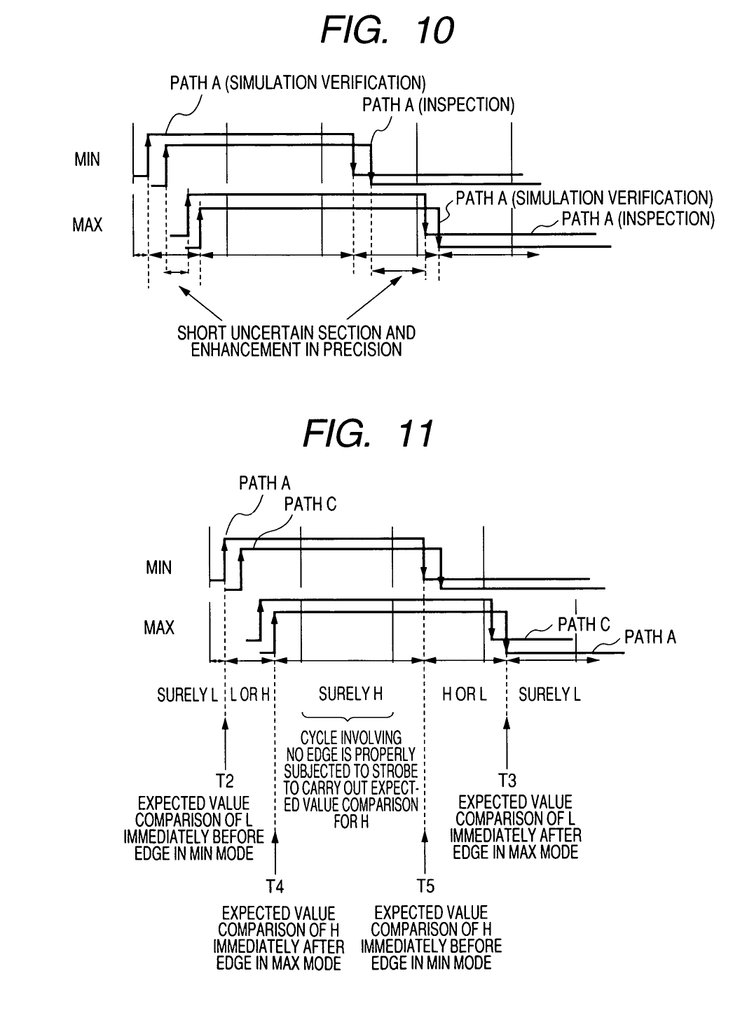

In a simulation verification, moreover, the delay conditions of MIN and MAX are the most strict and correspond to a variation in an actual LSI in many cases. In other words, in the inspection of the actual LSI using the inspecting device, there is a possibility that a variation in MIN and MAX might be smaller than MIN and MAX of a delay in the simulation verification (for example, an uncertain section in which the signals of T2 to T4 are “L” or “H” is reduced (FIG. 10). More specifically, by applying a signal transition time in the actual LSI which is extracted from the inspecting device, it is possible to carry out the inspection with higher precision as compared with the case in which the signal transition time in the simulation verification is applied.

FIG. 11 shows an example in which the paths cannot be distinguished in the inspection carried out by the method according to the invention. In this example, the inspection is carried out by surely setting the “L” signal before T2, setting the “L” or “H” signal from T2 to T4, and surely setting the “H” signal from T4 to T5 in consideration of the path A. In this case, if an output signal in the path C carries out a signal transition after MIN in the path A in an MIN mode and before MAX in the path A in an MAX mode, there is a high possibility that the path C cannot be distinguished accurately in the inspection for the path A. In this case, for example, it is possible to confirm the presence of a combination of the signal transition having a high possibility that the inspection cannot be carried out in an inspecting pattern to be used by previously extracting and putting a signal transition output delay time in each path by means of a static timing analyzing tool. By carrying out the previous confirmation, thus, it is possible to reduce an inspection error.

The embodiment is not restricted but the delay condition in the simulation verification and that in the inspection are not coincident with each other as described above. In the inspection according to the embodiment, therefore, the path cannot be reliably distinguished in some cases. As compared with a conventional strobe base technique for setting the expected value comparing time every cycle, however, precision in the inspection can be enhanced more greatly. In the simulation verification, the signal transition time in each path is determined in the MIN and MAX modes. Therefore, the paths can be distinguished from each other.

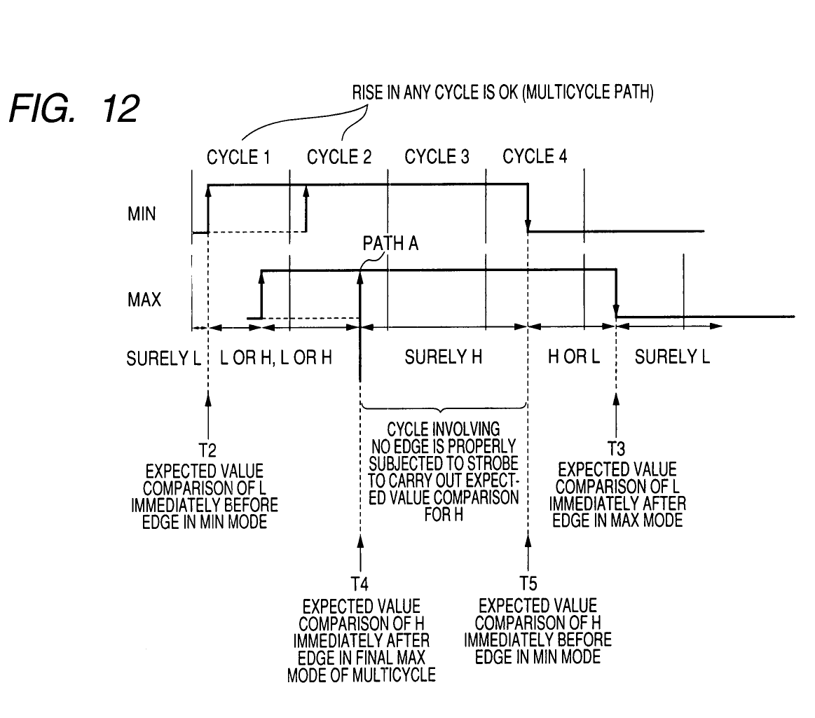

FIG. 12 shows an example of a multicycle path. In this example, when a signal is to be output through the path A, both of the cycles 1 and 2 can be applied. In this case, it is confirmed that the “L” signal is set immediately before T2 or a transition from “L” to “H” is carried out at T2 in the same manner. By the expected value comparison, however, a section of the “L” or “H” signal is extended across the cycles 1 and 2 and the transition from “L” to “H” in a final MAX mode in a multicycle is carried out at T4 or the “H” signal is set immediate after T4. In a conventional verifying technique, a cycle for carrying out the expected value comparison fluctuates in a multicycle path and it is hard to put an expected value in order to carry out the expected value comparison. The technique can flexibly correspond to a multicycle path. The correspondence to the multicycle path can also be applied to the inspection in the inspecting device.

### THIRD EMBODIMENT

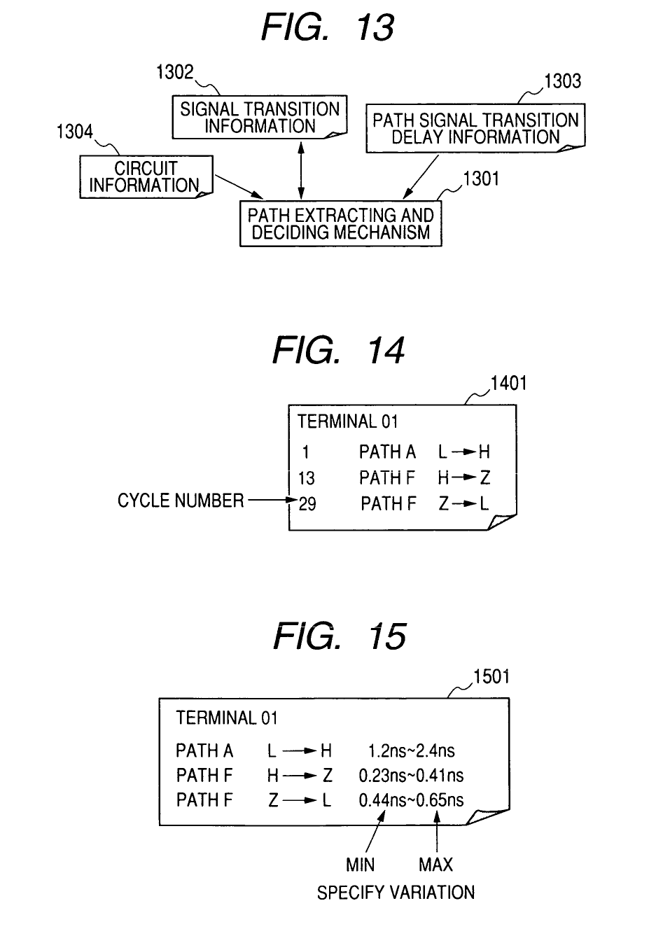

Next, a third embodiment of the invention will be described below. FIGS. 13 to 16 illustrate the third embodiment of the invention.

FIG. 13 shows a basic structure of a deciding device according to the third embodiment of the invention, the deciding device has a path extracting or deciding mechanism. Signal transition information 1302 of which summary is shown in 1401 of FIG. 14 and circuit information 1304 are input as input information to a mechanism 1301 to carry out a verification. In this case, a result of a transition of each signal to be a result of an operation of a circuit is compared with path signal transition delay information 1303 to be another input information (shown in 1501 of FIG. 15, for example) and any path through which a signal is output is thus extracted. A method of extracting a path by using the deciding device is shown in the flowchart of FIG. 6. On the other hand, the signal transition information 1302 has expected signal transition information in some cases. By comparing the paths and the signal transitions, it is decided whether the circuit is executed accurately. The path signal transition delay information 1303 is generated by a static timing analysis, for example.

A verification and an inspection are carried out with the structure according to the invention by using the method described with reference to the flowchart of FIG. 6. For the inspection, the mechanism may be incorporated in an inspecting board. Moreover, the signal transition change information may have a plurality of clocks (including asynchronous clocks).

By using the method in accordance with the invention, thus, it is possible to find the drawbacks of a circuit and a pattern in a more upstream process for a design with higher precision as compared with the conventional verifying method, resulting in an enhancement in quality of the design. Moreover, an inspection is carried out by using information about any path through which a signal transition is output. Finally, it is possible to finally inspect (test) the LSI with high precision and high quality.

Moreover, the signal transition information serves as a basis of an operation of an LSI, and is also supposed to be generated from a system verification on an upstream of a design. Furthermore, the signal transition information may include information about only a cycle in which a signal transition is generated, and it is not necessary to have input/output information about all cycles as in the conventional art. Therefore, it is also possible to expect the effect of reducing a size of the input information.

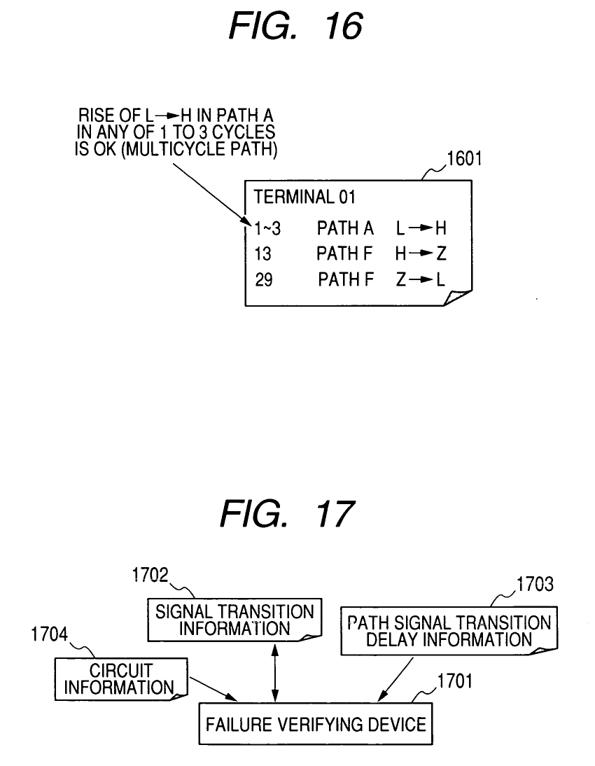

FIG. 16 shows a description example 1601 of the signal transition information in the multicycle path. In this example, a signal output through the path A and carrying out a transition from “L” to “H” may be set in any of 1 to 3 cycles. Referring to “1 to 3”, a description of “1-3” or “1, 2, 3” can also be supposed. In any case, an expression of the multicycle path can easily be described by using the method according to the invention. At the same time, it is possible to easily verify the multicycle path which is hard in a conventional simulation verification.

### FOURTH EMBODIMENT

Next, a fourth embodiment of the invention will be described.

The embodiment shows a technique for considering an influence on a signal path due to the way of giving a delay. A delay to be given to a circuit in the execution of a simulation verification includes a cell delay to be given to a logic cell in the circuit and a wiring delay to be given to a wiring. Moreover, the way of giving a delay includes a zero delay (either the cell delay or the wiring delay or the case in which the delay is given to neither of them) and a unit delay (a certain delay value is given to the cell delay and the wiring delay) in addition to ordinary delay precision. With a circuit which is synchronously designed and has no signal competition, a circuit operation can be verified through the zero delay or the unit delay. In some cases in which the zero delay or the unit delay is given, a delay calculation in the simulation verification can be carried out more easily and a processing speed can be higher as compared with the case in which an ordinary delay is given, which is advantageous.

For example, a difference in a signal path is not made between the case in which the verification is carried out through the zero delay or the unit delay and the case in which the verification is carried out with the ordinary delay, it can be decided that a delay margin is maintained sufficiently, a critical design portion is not present and a synchronism is held in the circuit. To the contrary, if the difference is made, it is possible to find a possibility that the circuit might have a problem in that the delay margin is not maintained sufficiently and the critical design portion is present. By confirming a resultant terminal, a path and transition information (a terminal, a path and a transition through which an expected operation cannot be carried out), particularly, it is possible to limit and examine any portion of the circuit which might have a problem.

By making a distinction between the case in which the cell delay and the wiring delay are caused to have an ordinary delay respectively and the case in which they are caused to have the zero delay and the unit delay respectively to carry out the verification, furthermore, it is possible to limit and examine either the cell delay or the wiring delay which has the problem when the difference in the signal path is made.

Moreover, it is also possible to employ a method of increasing delay precision in only a certain block in the circuit to be a verifying object and deteriorating the precision in the other blocks without simply gathering the cell delay and the wiring delay. In order to make an expected value comparing time clear, alternatively, it is also possible to increase the delay precision in only a clock system to be input to a cell in an output stage influencing a delay time for comparing expected values (from a flip-flop to an output buffer in a final stage) and a flip-flop in the final stage and reducing the precision in the other portions, thereby carrying out the verification. By increasing the delay precision in only a necessary circuit and reducing the precision in the other portions to fulfill the purpose of the verification, thus, it is possible to carry out the verification at a high speed.

In the case in which a frequency for carrying out the verification is changed in place of the delay information so that a difference is made on the signal path, moreover, it is possible to find a possibility that the circuit might have a problem in that a delay margin is not maintained sufficiently and a critical design portion is present. Thus, it is possible to limit and examine any portion in the circuit which might have the problem. For the problem of the critical design, particularly, it can be supposed that precision in the verification (sensitivity) is increased more greatly in a path comparison taking note of a signal transition time disclosed in the technique than a conventional strobe form.

### FIFTH EMBODIMENT

FIG. 17 is an explanatory diagram showing a verifying method according to a fifth embodiment of the invention.

In the fifth embodiment of the invention, the verifying method taking note of a signal transition time is applied to verify a failure.

In the verification of a failure, there is verified the number of failures in a circuit which can be detected by a test pattern used for the verification. As shown in FIG. 17, signal transition information (1702) has a terminal name, a cycle number, a path and a signal transition. In the embodiment, as shown in FIG. 17, a failure is verified by using a failure verifying device (1701) from signal transition information (1702), circuit information (1704) and path signal transition delay information (1703). In the verification of the failure, it is assumed that a failure is artificially set in a circuit and the signal transition information (1702) is input to the failure verifying device (1701), and the failure in the circuit is detected when an expected operation is not carried out. In the embodiment, by utilizing the “signal transition information 1702” and the “path signal transition delay information 1703” as information for detecting the failure, a capability of detecting a drawback of the circuit (a path through which a signal is output is varied) is increased more greatly as compared with the case in which a strobe is set every cycle to compare expected values as in the conventional art.

For example, a failure verification based on a single degradation failure has conventionally been carried out. However, there is a possibility that a new failure detection such as a delay failure can further be dealt with by the method according to the invention. For instance, description will be given with reference to FIG. 9. If L is maintained immediately after T4 in MAX when a signal is output from a flip-flop in a final stage of a circuit to an output terminal and a transition of the signal from “L” to “H” is carried out, there is also a possibility that a delay failure having a great delay can be detected.

### SIXTH EMBODIMENT

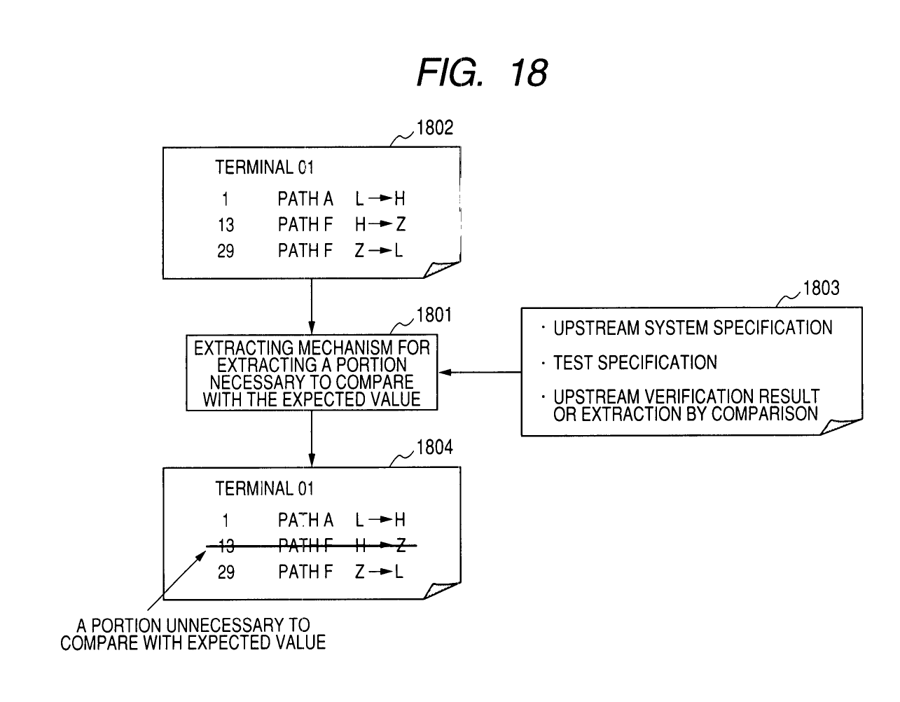

FIGS. 18 to 24 are diagrams for explaining a sixth embodiment of the invention.

In the sixth embodiment of the invention, a portion in which expected values do not need to be compared with each other is previously omitted (masked) from signal transition information and only a necessary expected value comparison is carried out. More specifically, it is possible to propose the case in which a cycle from a signal transition in an unnecessary path (a change in a signal) to a next signal transition is masked (omitted).

FIG. 18 shows a summary. This device comprises an expected value comparing unnecessary portion extracting mechanism 1801 for extracting an expected value comparing unnecessary portion from signal transition information 1802 based on expected value comparing unnecessary information 1803, and a signal transition of H→Z passing through a path F for a 13th cycle is omitted (masked) at an O1 terminal by the expected value comparing unnecessary portion extracting mechanism 1801. The expected value comparing unnecessary portion is extracted from a system specification or a test specification on an upstream of a design or a verification result on the upstream of the design as shown in the expected value comparing unnecessary information 1803. Alternatively, it is also possible to propose that the verification result on the upstream of the design and the signal transition information are compared with each other and are checked to automatically extract the expected value comparing unnecessary portion.

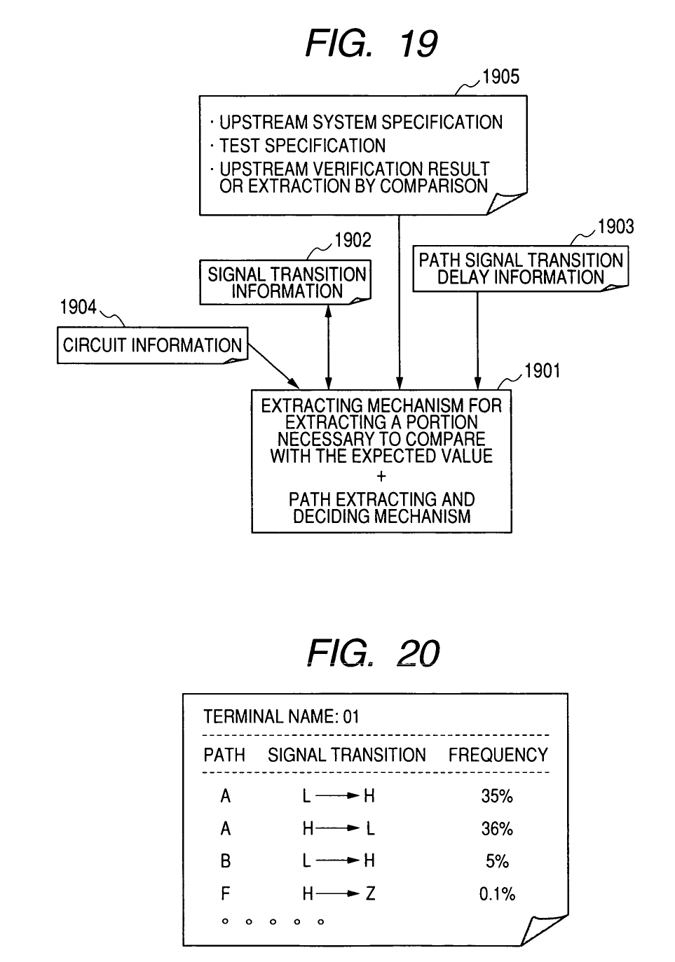

As shown in an example of FIG. 19, a path extracting and deciding mechanism 1901 may be caused to have an expected value comparing unnecessary portion extracting mechanism. In this case, an expected value comparing unnecessary portion is calculated (recognized) to decide an expected value in 1901.

FIG. 20 shows an example of a path frequency list. The path frequency list shows a frequency at which a path and a signal transition in a pattern intended for a verification are generated (for a whole transition). For example, a signal transition of “L”→“H” passing through a path A is generated at a rate of 35% of a whole pattern. There is a high possibility that an unexpected operation for a path and a transition having an extremely low frequency or an unexpected transition might be recognized based on a path frequency which is obtained. In some cases, the path frequency list is utilized as means for extracting the expected value comparing unnecessary portion.

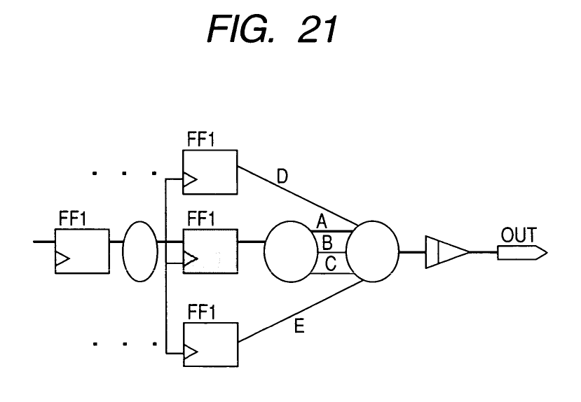

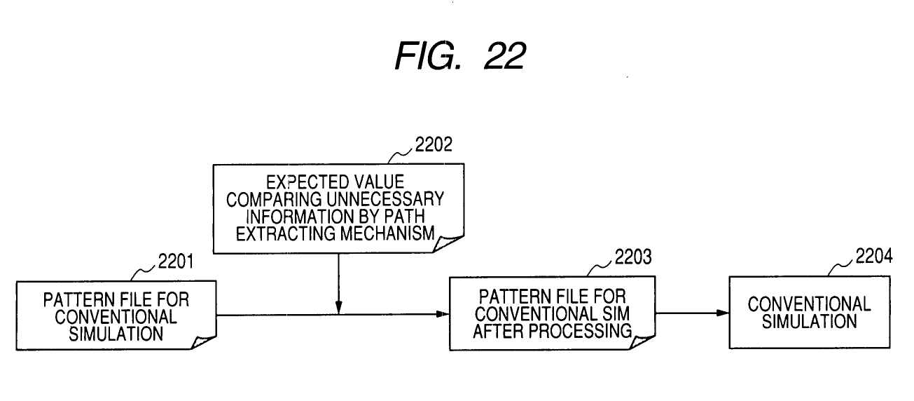

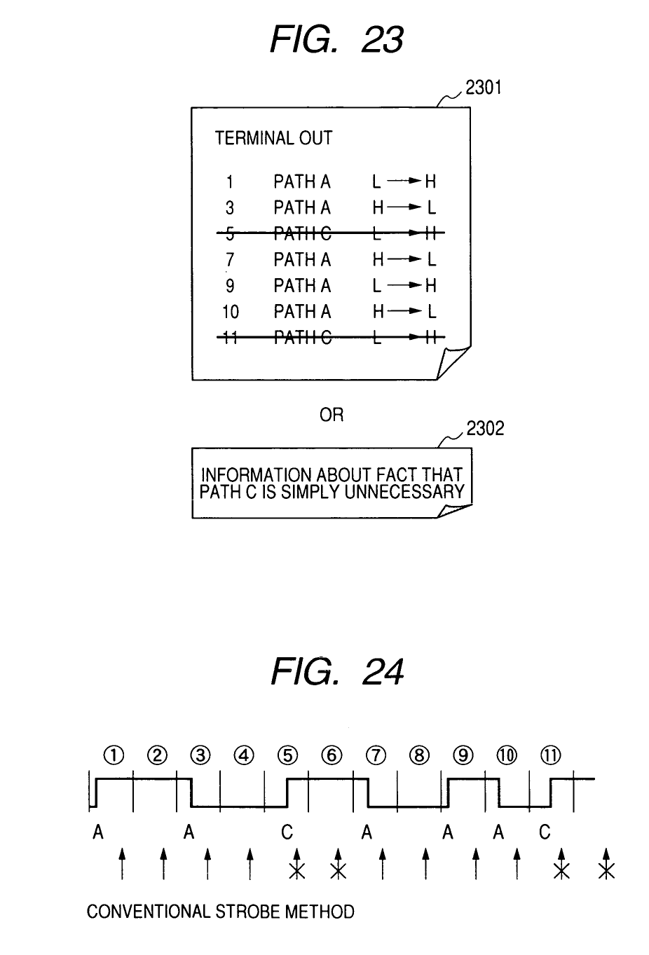

In some cases, the expected value comparing unnecessary portion is omitted and the expected values are then decided exactly on an edge base as shown in FIG. 19. However, it is also possible to propose a conventional technique (strobe base) for verifying an expected value comparing time every cycle in residual portions. The case in which a circuit is verified as shown in FIG. 21 will be taken as an example. FIG. 22 shows a flow. Information 2202 clearly describing an expected value comparing unnecessary portion obtained by the path extracting mechanism is given to a test pattern file 2201 for a simulation according to the conventional art. The information clearly describing the expected value comparing unnecessary portion clearly is shown as an example in FIG. 23 (2301). A signal transition of “L”→“H” in a path C for a fifth cycle is not required, for example. The information may be a describing method (2302) of “the path C is unnecessary” or may be only expected value comparing unnecessary portion information.

Based on this information, a test pattern file for a simulation is processed (2203) and a conventional strobe base simulation verification 2204 is carried out. The summary of a simulation verification is shown in FIG. 24. Based on the information which clearly describes the expected value comparing unnecessary portion as illustrated in FIG. 23, masking is carried out from the transition of “L”→“H” passing through the path C for the fifth cycle to a next transition (that is, up to a sixth cycle) and is carried out from a transition of “L”→“H” for an 11th cycle to a next transition, and a strobe is set in residual cycles to verify a simulation.

By using the technique, thus, it is not necessary to carry out an unnecessary expected value comparison so that a verification efficiency can be increased and precision in a verification can be enhanced at the same time. Moreover, the technique can be applied to an inspection using an inspecting device in addition to the verification.

### SEVENTH EMBODIMENT

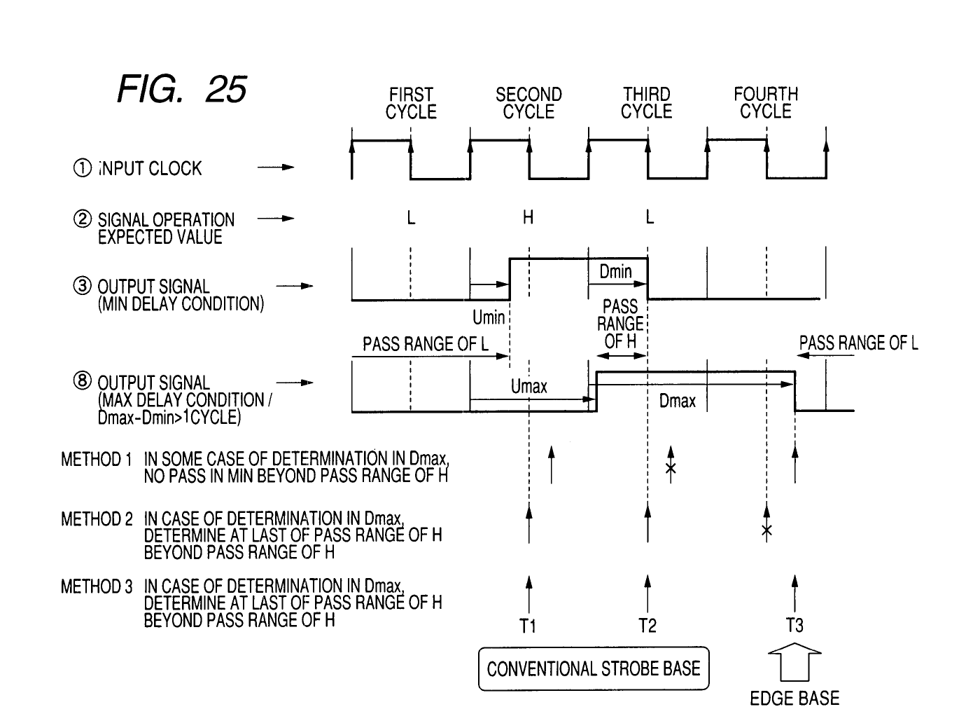

FIGS. 25 to 29 are explanatory diagrams showing a seventh embodiment of the invention.

For a fusion of a conventional strobe base verification and an edge base, the following case can also be proposed. In some cases, a signal causes an overcycle in the conventional strobe base verification. In these cases, however, the edge base verification is combined in a high-speed LSI verification. For example, in the case in which a difference between MIN and MAX is greater than one cycle as shown in FIG. 25, there is no strobe time that an expected value comparison can be stably carried out over a whole cycle. In a certain cycle in each of methods 1 and 2, it is necessary to mask an expected value. In this case, it is possible to carry out a verification in all cycles without performing masking by setting T1 and T2 to the conventional strobe base and only T3 to the edge base.

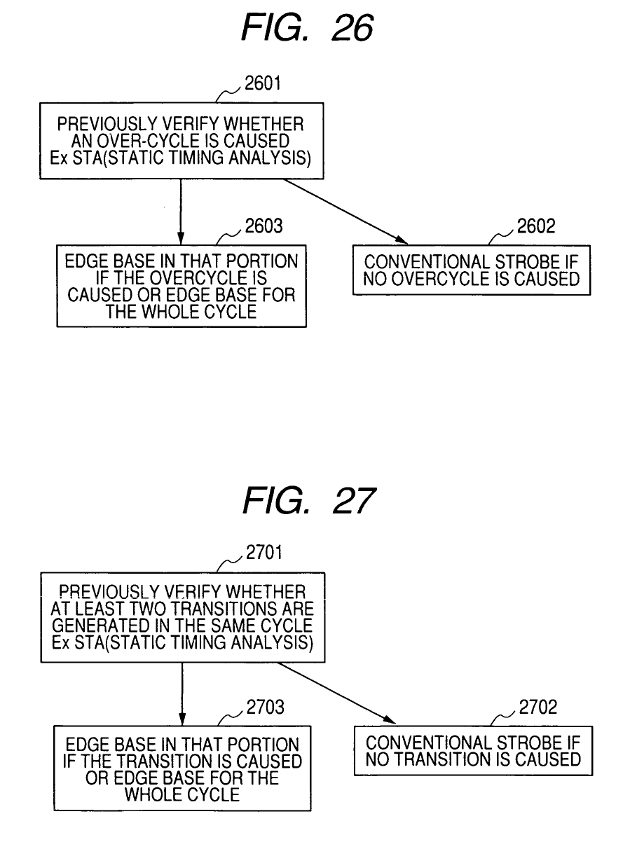

FIG. 26 shows a specific flow. First of all, whether an overcycle is generated in a static timing analysis is verified previously (2601). If the overcycle is not generated, a conventional strobe verification is carried out (2602). If the overcycle is generated, the edge base verification is carried out in only the same cycle. As a matter of course, the edge base may be employed in all of the cycles (2603).

FIG. 27 shows an example of the case in which at least two transitions are generated in the same cycle. In the case in which at least two transitions are generated in the same cycle, the verification cannot be carried out stably in the conventional strobe verification. Also in the case, first of all, whether at least two transitions are generated in the same cycle by the static timing analysis is previously verified (2701). If there is no transition, the conventional strobe verification (2702) is carried out. If at least two transitions are generated, the edge base verification is carried out in only the same cycle. As a matter of course, the edge base may be employed in all of the cycles (2703). If a signal section is too short as a result of the transition, moreover, a decision of an omission from a determining object may be made.

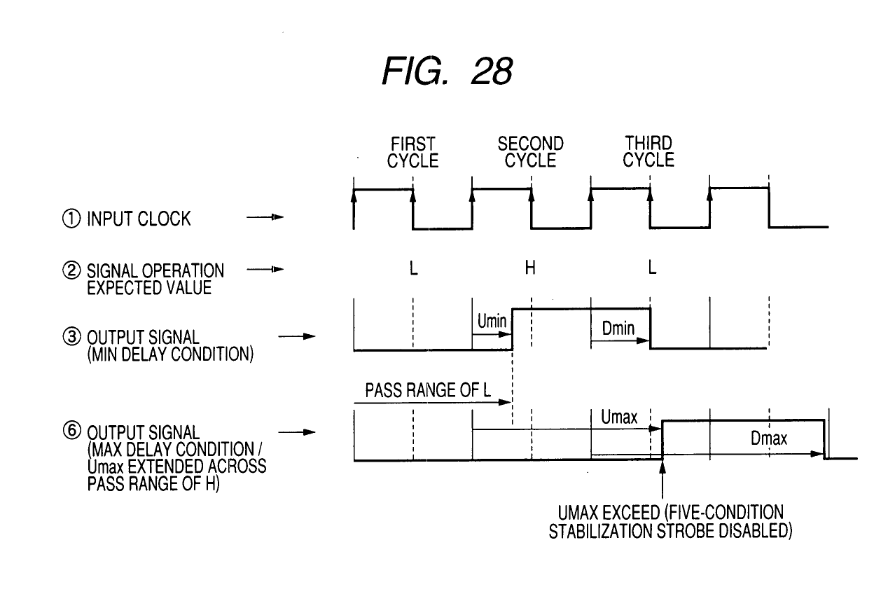

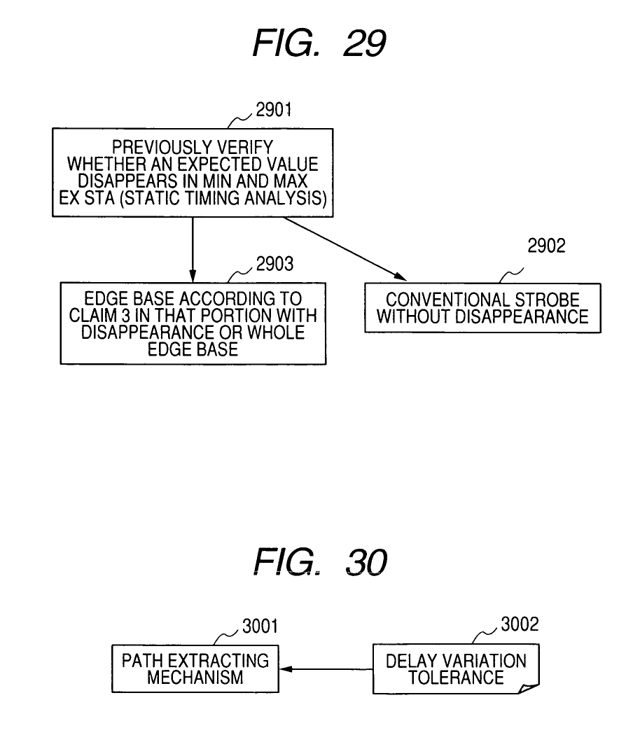

FIG. 28 shows an example in which an expected value disappears when a synthetic decision is made on MIN and MAX conditions in the conventional strobe base (in the example, an “H” signal expected value disappears). Also in this case, a previous verification is carried out through a static timing verification (2901) as shown in FIG. 29. If the expected value does not disappear, the conventional strobe verification (2902) is carried out. If the expected value disappears, the verification is carried out in combination of the edge base (2903).

Thus, the expected value is masked or the verification cannot be carried out sufficiently in only the conventional strobe base. However, it is possible to carry out the verification with high precision without masking by combining the edge base. Moreover, the technique can also be applied to an inspection using an inspecting device in addition to the verification.

### EIGHTH EMBODIMENT

Next, description will be given to an eighth embodiment of the invention.

A dynamic simulation tool or a static timing analyzing tool is used to extract a path as shown in FIG. 6. In some cases, a simulation and precision in a static timing analysis are not perfectly coincident with each other and delay values to be originally coincident with each other are finely different from each other so that a path cannot be extracted due to a delay calculating tool, a difference in a result or an error of a calculation depending on a tool (round-off or round-up). In the eighth embodiment of the invention, therefore, a delay variation tolerance (3002) is given to a path extraction (3001) as shown in FIG. 30.

The way of giving the tolerance is as follows. Precision in a library of a tool to be used may be extracted to give the tolerance, the number of stages of a gate from a flip-flop in a final stage to an output which influences a signal transition is extracted to give the tolerance or delay values in all paths are extracted to give the tolerance within such a range that a path extracting error is not generated. By giving the tolerance, thus, it is possible to reliably extract a path.

### NINTH EMBODIMENT

Next, description will be given to a ninth embodiment of the invention.

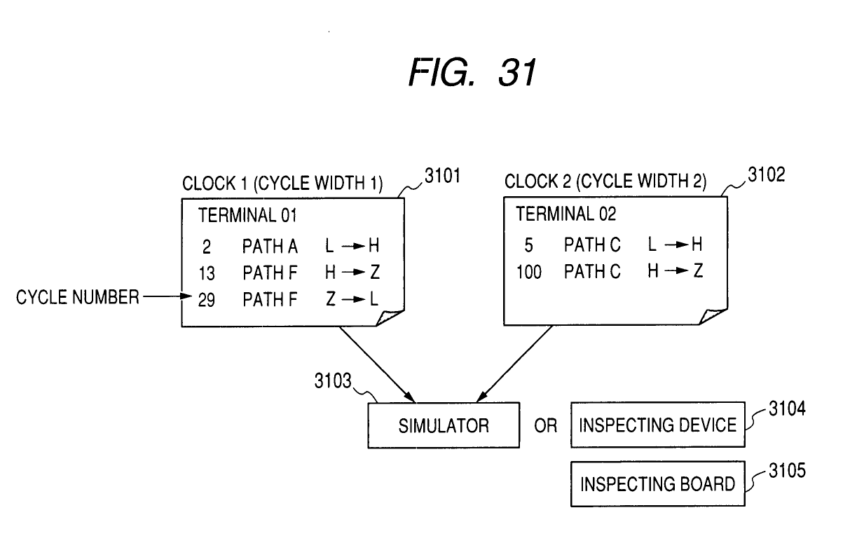

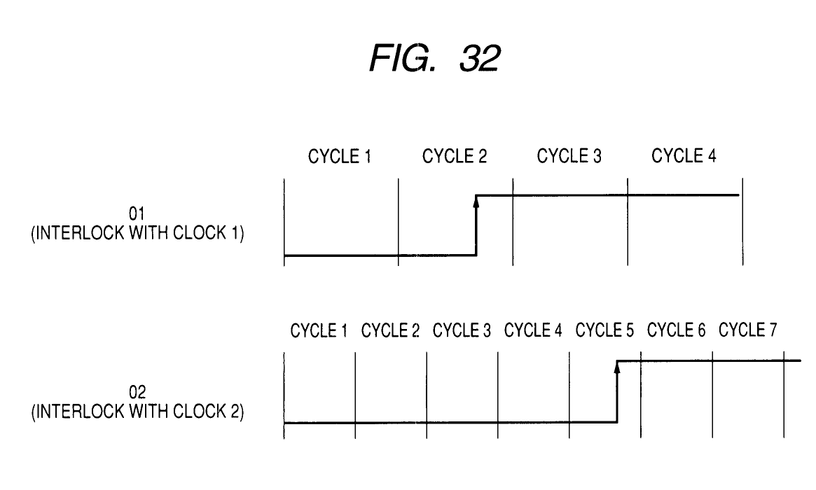

In the embodiment, there will be described an example of a verifying method in an LSI having a plurality of clocks in the first embodiment. In the embodiment, description will be given to the case in which there is a plurality of clocks of a clock 1 (a cycle width 1) and a clock 2 (a cycle width 2) as shown in FIGS. 31 and 32. Signal transition information 3101 of the clock 1 and signal transition information 3102 of the clock 2 are input to a simulator 3103. An inspecting device 3104 or an inspecting board 3105 may be used. A plurality of clocks may be asynchronous.

FIG. 32 shows an example of a waveform related to the signal transition information illustrated in FIG. 31. A signal transition of L→H is generated through a path A in a cycle 2 at a terminal O1. On the other hand, a signal transition of L→H is generated through a path C in a cycle 5 at a terminal O2.

Conventionally, in the case in which there is a plurality of clocks (including asynchronous clocks) having different cycle widths, for example, an inspection is finally carried out (synchronously) in the same cycle width within the limit of an inspecting device so that the cycle width is to be adapted (synchronized) in a test pattern. By using the method according to the embodiment, however, it is possible to easily carry out an inspection and a related verification to which a plurality of clocks is exactly applied.

As described above, according to the invention, it is possible to find the drawbacks of a circuit and a pattern with higher precision in a more upstream process for a design. Therefore, the invention is effective for inspecting a high integrated LSI and an inspection (test) can be implemented with high precision and quality.

What is claimed is:

1. A method of verifying a semiconductor integrated circuit which sets an expected value comparing time onto a signal transition point and verifying whether a circuit is operated accurately or not.

2. The method of verifying a semiconductor integrated circuit according to claim 1, comprising a path extracting step of extracting a path in a circuit through which a signal is output based on circuit information of a semiconductor integrated circuit and signal transition information of the semiconductor integrated circuit, whether the circuit is operated accurately being verified.

3. The method of verifying a semiconductor integrated circuit according to claim 1, wherein whether a circuit is operated accurately is verified based on information about a path in a circuit through which a signal output from an external terminal of the semiconductor integrated circuit passes which is obtained by using information extracted at the path extracting step.

4. The method of verifying a semiconductor integrated circuit according to claim 2, wherein the path extracting step serves to set an expected value comparing time onto a signal transition point obtained from the signal transition information and to extract a path.

5. The method of verifying a semiconductor integrated circuit according to claim 2, wherein the path extracting step serves to set an expected value comparing time onto a signal transition point and a signal stabilizing section and to extract a path.

6. The method of verifying a semiconductor integrated circuit according to claim 2, wherein the path extracting step serves to set an expected value comparing time based on a signal transition point obtained from an inspecting device and to extract a path.

7. The method of verifying a semiconductor integrated circuit according to claim 2, wherein the path extracting step serves to set an expected value comparing time onto a signal transition point in the earliest case and a signal transition point in the latest case when a signal might be extended across a plurality of cycles.

8. The method of verifying a semiconductor integrated circuit according to claim 2, wherein the path extracting step is executed by a path extracting mechanism for extracting a path which indicates a path in a circuit through which a signal is output from an external terminal in an operation of the semiconductor integrated circuit.

9. The method of verifying a semiconductor integrated circuit according to claim 2, wherein a path is decided by a path deciding mechanism for deciding a path which indicates a path in a circuit through which a signal is output from an external terminal in an operation of the semiconductor integrated circuit from path information extracted at the path extracting step.

10. The method of verifying a semiconductor integrated circuit according to claim 2, comprising a comparing step of comparing a change in a path through which a signal is output from an external terminal in the case in which delay information is taken into consideration and the case in which the delay information is not taken into consideration,
whether a circuit is operated accurately being verified based on a result of the comparison.

11. The method of verifying a semiconductor integrated circuit according to claim 2, wherein it is ascertained whether a path through which a signal is output from an external terminal is changed or not in the case in which delay information is taken into consideration and the case in which the delay information is not taken into consideration in a wiring delay and a cell delay, and whether a circuit is operated accurately is thus verified.

12. The method of verifying a semiconductor integrated circuit according to claim 2, wherein a circuit operating frequency is varied to ascertain whether a path through which a signal is output from an external terminal is changed or not, and whether a circuit is operated accurately is thus verified.

13. The method of verifying a semiconductor integrated circuit according to claim 2, further comprising a step of previously omitting a result comparison which does not require an expected value comparison by means of an expected value comparing unnecessary portion extracting mechanism prior to the path extracting step.

14. The method of verifying a semiconductor integrated circuit according to claim 2, further comprising a step of previously omitting an expected value comparison for a path in which a path frequency has a predetermined value or less by means of a path frequency extracting mechanism for extracting information about a frequency of a path through which a signal is sent prior to the path extracting step.

15. The method of verifying a semiconductor integrated circuit according to claim 2, further comprising a step of extracting a signal path which causes an overcycle.

16. The method of verifying a semiconductor integrated circuit according to claim 2, further comprising a step of extracting a signal path in which a signal transition is carried out at plural times in the same cycle.

17. The method of verifying a semiconductor integrated circuit according to claim 2, further comprising a step of extracting a cycle in which an expected value comparison cannot be stably carried out in a plurality of delay modes.

18. The method of verifying a semiconductor integrated circuit according to claim 2, further comprising a step of giving a delay variation when extracting a path.

19. A method of checking a semiconductor integrated circuit by a tester using the method of verifying the semiconductor integrated circuit according to any of claims 1 to 18, wherein whether a circuit is operated accurately is inspected by using information about a path in the circuit through which a signal is output in an operation of the semiconductor integrated circuit.
